(19) United States
(12) Patent Application Publication
(10) Pub. No.: US 2010/0219064 A1
(43) Pub. Date: Sep. 2, 2010

(54) FILM FORMING METHOD

(75) Inventors: Akira Sakai, Kawasaki-shi (JP); Yasufumi Asao, Atsugi-shi (JP); Yohei Ishida, Kawasaki-shi (JP); Yoichi Hoshi, Atsugi-shi (JP); Kensuke Yagi, Atsugi-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/096,747

(22) PCT Filed: Mar. 3, 2008
(86) PCT No.: PCT/JP2008/054231

§ 371 Date: Jun. 9, 2008

(30) Foreign Application Priority Data
Mar. 2, 2007 (JP) 2007-053254

(51) Int. Cl. C23C 14/34

(52) U.S. Cl. 204/192.26

(57) ABSTRACT

A film forming method is constituted by forming a silicon oxide film on a substrate by causing silicon generated by sputtering with silicon as a target to be incident on the substrate from an oblique direction while supplying oxygen gas onto the substrate.

### TECHNICAL FIELD

The present invention relates to a silicon oxide film forming method, an alignment film and a liquid crystal optical device. Specifically, the present invention relates to a forming method of an inorganic liquid crystal alignment film and a liquid crystal optical device prepared by using the forming method.

### BACKGROUND ART

An optical device including a liquid crystal such as a liquid crystal display or a liquid crystal light valve is constituted by a pair of substrates disposed opposite to each other and a liquid crystal disposed between the pair of substrates. An alignment state of the liquid crystal is changed by applying a voltage between electrodes provided to one or both of the substrates, so that it is possible to control an optical property such as birefringence or optical activity.

On at least one of the substrates, an alignment film for aligning the liquid crystal is formed and when the voltage is not applied, an alignment direction of the liquid crystal is regulated by the alignment film. A typical alignment film forming method is a rubbing method in which a polymeric film is applied onto the substrate and a surface of the substrate is rubbed with a cloth in one direction. The rubbing method is capable of imparting a uniform alignment characteristic to a substrate with a large area, so that it is suitable for forming an alignment film on a large-size glass substrate. A polymer film material most frequently used in the rubbing method is polyimide. Polyimide has a high durability against a change in light or temperature in such an environment that it is used in an ordinary display.

However, in a liquid crystal device used as an optical shutter for a projection type display, the liquid crystal is exposed to intense light, so that the polymeric alignment film is liable to be deteriorated. As a result, high durability is not expected. Even the polyimide alignment film chemically stable compared with other polymeric materials, breakage of its chemical structure is caused to occur by intense light exposure, thus resulting in such a problem that the polyimide alignment film is not used for a long time.

Other than the rubbing method of the polymeric film, a method of causing anisotropy by forming a minute structure of an inorganic material on a substrate surface is also known. A typical example thereof is so-called oblique deposition in which silicon monoxide or silicon dioxide is obliquely deposited on the substrate. A film obtained by the oblique deposition is microscopically constituted by columns of several nanometers to several hundreds of nanometers inclined with respect to the substrate. By the inclination of these columns, an alignment direction of the liquid crystal is controlled.

An inorganic material such as silica or the like is chemically stable and excellent in durability against light, compared with an organic material. For this reason, the oblique deposition is being reconsidered as an alignment film of a liquid crystal device for the purpose of a projector. Japanese Laid-Open Patent Application (JP-A) 2003-129228 discloses an embodiment in which a three-plate type liquid crystal projector is constituted by a liquid crystal light valve using an oblique deposition film.

In the 53th Spring Meeting Proceedings (March, 2006) of the Japan Society of Applied Physics, pp. 655-“High-speed sputtering film forming method of TiO₂ thin film using two sputtering sources”, a method of forming an oxide film at high speed is disclosed. In order to prepare TiO₂ thin film, supply of Ti sputtering particles and supply of oxygen radicals are performed by the two sputtering sources and oxidation of sputtering Ti from a Ti target is performed by the supply of oxygen radicals. As a result, it is possible to form the TiO₂ thin film on an obliquely disposed substrate.

In the case of this TiO₂ thin film, it is disclosed that radicalization of oxygen is essential. In this case, in order to enhance the oxidizing power, it is necessary to additionally provide a plasma source, thus resulting in increases in production cost, production management items, and thin film production cost. For this reason, it is desired that an inexpensive production apparatus with a simpler constitution is provided without requiring additional equipment such as oxygen activation means.

JP-A 2005-84142 discloses a method in which sputtering with SiO₂ or SiO target is performed by using a magnetron sputtering apparatus to deposit SiO₂ or SiO on an obliquely disposed substrate so as to form a liquid crystal alignment film.

In production of a liquid crystal apparatus, it is desired that an alignment film is formed with high throughput. However, in oblique sputtering using the SiO₂ target, a high deposition speed cannot be obtained. Even in reactive sputtering in which a sputtering rate is increased by using an Si target and deposition is effected in an oxygen atmosphere, it is pointed out that the presence of oxygen at the SI target surface leads to a lowering in sputtering rate.

### DISCLOSURE OF THE INVENTION

A principal object of the present invention is to provide a method for forming a film of an inorganic material excellent in durability at a deposition speed higher than that in a conventional method.

Another object of the present invention is to provide a liquid crystal alignment film obtained through the film forming method and a liquid crystal optical device using the liquid crystal alignment film.

According to an aspect of the present invention, there is provided a method of forming a silicon oxide film on a substrate comprising steps of: sputtering a silicon target to generate silicon particles; bombarding the substrate with the silicon particles from an oblique direction while supplying oxygen gas onto the substrate.

The present invention is capable of providing a forming method of a silicon (Si) oxide film in which the Si oxide film excellent in durability can be obtained at a high deposition speed.

The present invention is also capable of providing an alignment film of an inorganic material excellent in durability at a high deposition speed.

The present invention is further capable of providing a liquid crystal optical device using the above described alignment film.

The Si oxide film forming method of the present invention can form the Si oxide film excellent in durability at a high deposition speed, so that the forming method can be utilized in a production process of a liquid crystal alignment film or a liquid crystal optical device.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1 is a schematic view of a sputtering film forming apparatus used in an Si oxide film forming method according to the present invention.

FIG. 2A is a graph showing a change in transmittance with respect to an incident angle in the Si oxide film forming method of the present invention;

FIG. 2B is a photographic image, observed through a scanning electron microscope (SEM), of an alignment film prepared by the Si oxide film alignment film of the present invention; and FIGS. 2C(a) and 2C(b) are schematic views showing cross sections of an alignment film prepared by the Si oxide film alignment film of the present invention.

FIG. 3 is a schematic view showing an embodiment of a cross-sectional constitution of a liquid crystal optical device of the present invention.

FIG. 4 includes schematic view for illustrating alignment states of liquid crystal molecules in liquid crystal cells.

FIG. 5 is a schematic view of a sputtering film forming apparatus used in Example 1 of the present invention.

FIG. 6 is a schematic view of a sputtering film forming apparatus used in a liquid crystal alignment film forming process in the present invention.

FIG. 7A is a graph showing a cathode voltage-current characteristic of an Si cathode and an SiO₂ cathode in Example 2 of the present invention; and FIG. 7B is a graph showing a cathode voltage-current characteristic of the SiO₂ cathode when an oxygen flow rate is changed.

FIG. 8 is a graph showing an influence (voltage-current characteristic) of the SiO₂ cathode on the Si cathode in Example 2 of the present invention.

FIG. 9 is a graph showing a transmittance characteristic (incident angle θ=80 deg.) of SiO₂ in Example 2 of the present invention.

FIG. 10 is a graph showing a transmittance characteristic (incident angle θ=40 deg.) of SiO₂ in Example 2 of the present invention.

FIG. 11 is a graph showing a deposition speed on a substrate when an oxygen mode sputtering with an SiO₂ target in Example 2 of the present invention is performed.

FIG. 12 is a schematic view of a substrate arrangement used for evaluating an amount of Si emitted from a sputtering source when the oxygen mode sputtering with the SiO₂ target in Example 2 of the present invention is performed.

### BEST MODE FOR CARRYING OUT THE INVENTION

Hereinbelow, the present invention will be described more specifically.

In semiconductor manufacturing, sputtering is widely used. Energy of sputtering particles is typically several tens of eV. On the other hand, when a liquid crystal alignment film is formed by a conventional oblique deposition method, vapor of a deposition substance is generated by subjecting a deposition source to heating or electron beam irradiation, so that kinetic energy of vaporized deposition particles is on the order of thermal energy, i.e., at most 0.1 eV. Sputterred particles have a larger kinetic energy than the vapor in conventional oblique deposition by two or more digits. After the sputtered particle arrive on the substrate, they would move violently on the substrate. Therefore, it might be expected that a column shape is different from that of the oblique deposition.

However, when the present inventors try to perform the sputtering, it is confirmed that a film of SiO, SiO₂ or a mixture thereof obtained by obliquely irradiating the substrate with sputtering Si with high energy (hereinafter inclusively referred to as an “Si oxide”) has such an integrated structure that columnar structures grown obliquely from the substrate are aggregated to form a thick column of several tens of nm or more through a cross-section scanning electron microscope. Further, it is clarified that this Si oxide film having the column structure has a property of vertically align liquid crystal molecules and a degree of verticality is uniform. When the liquid crystal molecules are inclined by voltage application, it is also possible to confirm that the liquid crystal molecules are inclined with an inclined surface which precisely coincides with a sputtering direction.

A liquid crystal mode in which liquid crystal molecules are vertically aligned under no voltage application and are aligned in an inclined state is known as a vertical alignment (VA) mode. In other words, an oblique deposition film by the sputtering can be said to be suitable for forming a VA mode liquid crystal device.

The properties of the conventional oblique deposition film, i.e., the vertical alignment characteristic and inclined azimuth anisotropy are kept in the sputtering film formation in the present invention although the resultant column is thick. As described above, the present invention not only takes advantages of the conventional oblique deposition film with respect to the liquid crystal alignment but also realizes high durability performance.

The inorganic alignment film is excellent in durability when compared with the case of using an organic alignment film subjected to rubbing treatment. In addition, the inorganic alignment film formed by the film forming method of the present invention has the following advantages even when compared with the inorganic alignment film formed by the conventional oblique deposition.

A first advantage is that a column is formed thickly, so that high durability performance is exhibited while retaining a vertical alignment performance. A second advantage is that a large deposition speed is ensured compared with a conventional reactive sputtering. A third advantage is that a simple structure such that an oxygen supplying means is disclosed close to the substrate can be used.

Oxygen gas supplied in the neighborhood of the substrate is not required to be activated and can also achieve an effect enough to align the liquid crystal molecules in a small amount necessary to oxidize Si. Further, the Si oxide film forming method of the present invention can terminate dangling bonds at surfaces of the Si oxide film by introducing oxygen to the substrate surface in the case where a thickness distribution occurs in the sputtering film formation using the obliquely disposed substrate. As a result, a surface diffusion distance of film forming particles is increased, thus reducing a degree of the thickness distribution. By increasing a substrate temperature, the surface diffusion of the film forming particles is further accelerated, thus further uniformizing the film thickness.

### Example 1

### Sputtering

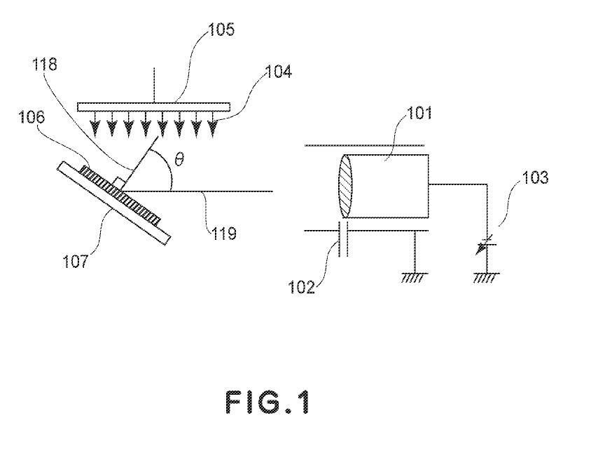

FIG. 1 is a substrate showing a sputtering film forming apparatus used in the Si oxide film forming method of the present invention. Referring to FIG. 1, an Si target 101 is a cathode of Si as a principal material and constitutes a magnetron sputtering apparatus. A sputtering gas supply pipe 102 is capable of supplying inert gases Ar, Xe and Kr singly or in mixture. A sputtering power source 103 is a RF/DC/pulse power source which determines a frequency, power, voltage, pulse ratio, and pulse frequency within a range not causing abnormal discharge at the Si target 101. A pressure of a vacuum furnace is adjusted by an unshown evacuation adjusting valve to supply electric power from the power source 103, so that it is possible to easily generate plasma in the neighborhood of the Si target 101 as the cathode.

At an outer peripheral surface of the Si target 101, a cylindrical member may be provided. This cylindrical member is provided for the purposes of enhancing directivity of sputtering Si from the Si target 101, suppressing diffusion of oxygen gas supplied from an oxygen gas supply pipe 105 toward the Si target 101, stabilizing the plasma generated in the neighborhood of the Si target 101, and so on. In order to suppress the abnormal discharge. The cylindrical member may preferably be constituted by an electroconductive material.

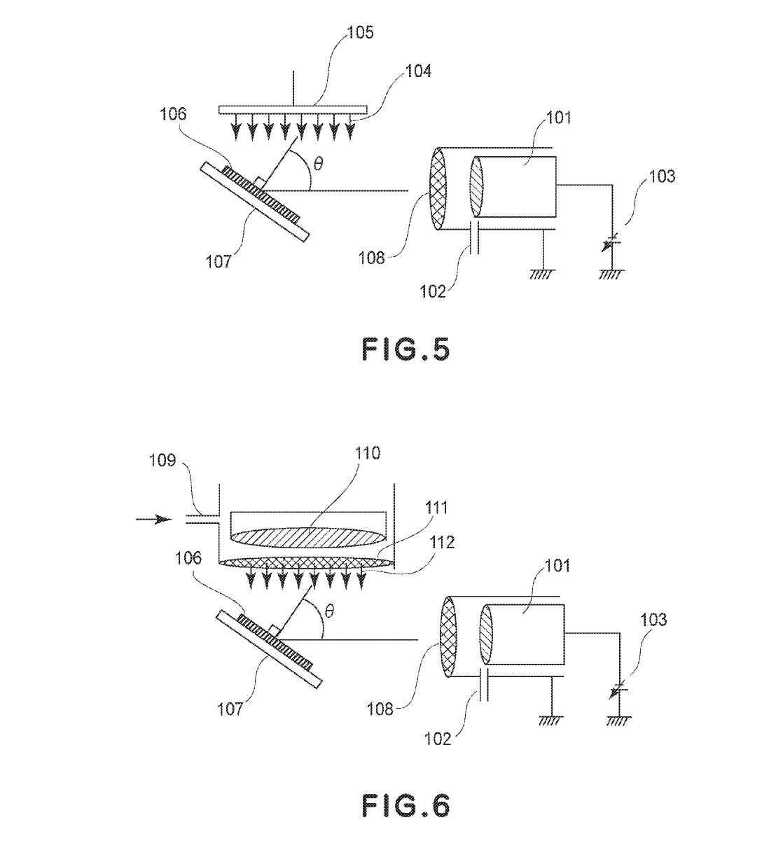

Further, as shown in FIG. 5, it is possible to cover a part or all of the surface of the Si target 101 with a mesh-like member (mesh) 108. An aperture ratio of the mesh may preferably be 20% or more and 90% or less in consideration of permeability from the Si target 101 to the mesh. Further, from the viewpoint of separation of sputtering gas and oxygen gas introduced in the neighborhood of the substrate for oxidation, the aperture ratio of the mesh may preferably be 30% or more and 80% or less. In this embodiment, the aperture ratio is set to 60% and oxidation of an oblique deposition film is performed. As a result, it is possible to suppress the diffusion of the oxygen gas supplied from the oxygen gas supply pipe 105 toward the Si target 101. Further, it is possible to stabilize the plasma generated in the neighborhood of the Si target 101. The mesh-like member 108 may preferably be constituted by an electroconductive member from the viewpoint of abnormal discharge suppression.

The oxygen gas supply pipe 105 supplies oxygen gas toward a substrate 106 and a substrate holder 107 in a direction 104. The oxygen gas supply pipe 105 may preferably have a shower structure for supplying oxygen to the substrate 106 uniformly but may also have a single pipe structure so long as it can supply oxygen to the substrate 106. With respect to a direction of a supply opening of the single pipe, it can be appropriately adjusted so long as oxygen gas supply to the substrate 106 can ensured but may preferably be one which is not directed toward the Si target 101 in order to suppress the diffusion of oxygen gas toward the surface of the Si target 101. The shape of the supply opening of the oxygen gas supply pipe 105 may be such a horn shape that the diffusion is accelerated. In order to efficiently supply the oxygen gas to the substrate 106, it is also possible to supply inert gas in mixture with the oxygen gas.

In the present invention, the oxygen gas has a sufficient oxidation power without being activated but may also be supplied after being activated. As an oxygen activation means, it is possible to employ ultraviolet irradiation or it is also possible to supply electromagnetic energy to the oxygen gas to generate plasma, which is supplied to the substrate 106. By appropriately setting an oxygen flow rate and target electric power in an oxygen-mode sputtering by using a sputtering apparatus with an oxide target, it is also possible to use the means as a oxygen radical supply source.

The substrate 106 is held on the substrate holder 107. The substrate 106 is disposed and inclined so as to provide an incident angle θ formed between a normal 118 to the substrate 106 and an incident direction 119 of Si from the Si target 101 toward the substrate surface. The substrate holder 107 contains a heater, so that it can set a temperature of the substrate 106 in a range from room temperature to 350° C. to cause deposition of Si.

The incident angle θ is continuously adjustable and is fixed by being set in a range in which the oxidation sufficiently proceeds.

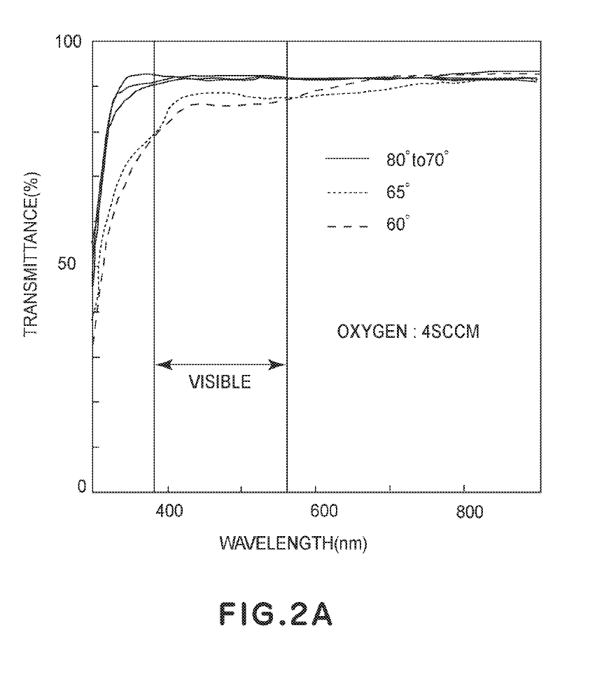

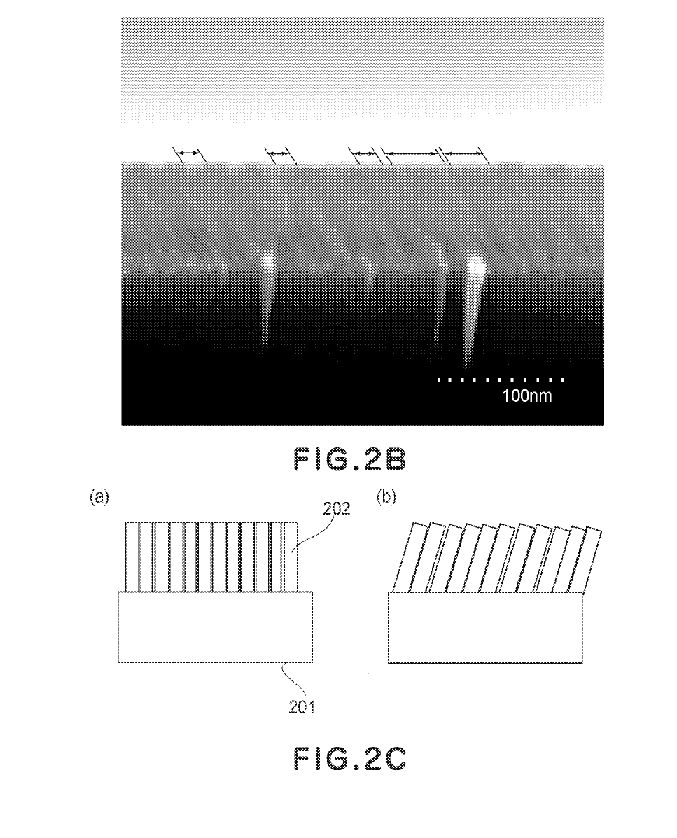

Specifically, the incident angle θ may desirably be 60 deg. or more and 90 deg. or less, preferably 60 deg. or more and 85 deg. or less. A glass substrate is set in a substrate holder. An Si sputtering film was prepared at room temperature under a constant film forming condition and a constant oxygen gas introducing condition except that the incident angle θ is changed to 60 deg., 65 deg., 75 deg., 80 deg., and 85 deg. An oxidation state of the Si sputtering film was evaluated through measurement of a transmittance. The results are shown in FIG. 2A.

As a result, it is understood that the transmittance of 90% or more is kept in visible region at the incident angles θ of 70 deg. or more. This is because a composition change from an Si film to an SiO₂ film is caused to occur. The SiO₂ film can be confirmed by dominant SiO₂ bond energy through ESCA analysis. In this way, it is found that not only a column structure can be formed by sputtering Si so as to be obliquely incident on the substrate to form a column structure but also sufficient oxidation can easily be realized by supplying oxygen gas to the substrate surface without oxidizing the oxygen gas.

Further, from a cross-sectional observation image of a scanning electron microscope (SEM) shown in FIG. 2B, the column structure can be confirmed. From FIG. 2B, a width of the column is 10 nm or more. The column structure varies depending on the incident angle θ of the sputtering particles, so that an column angle is largely inclined (changed) when the incident angle θ is increased. As a result, a gap between columns is increased, so that it is expected that uncombined hand of Si is increased. As a result, diffusion of oxygen into the film and reaction with the Si uncombined hand are promoted to provide an SiO₂ film which is further oxidized (FIGS. 2C(a) and 2C(b)).

A sputtering condition and an oxidation condition are shown in Table 1 below.

A deposition speed is 25 nm/min even at the incident angle θ of 85 deg., thus being 5 times higher than a deposition speed of 5 nm/min obtained in conventional reaction sputtering. Accordingly, it is possible to prepare a high-speed sputtering oxide film.

TABLE 1
(SiO₂ obliquely incident film preparation condition)

| Target | | |
|---|---|---|
| (33 mmφ) | Si target | Oxygen gas supply pipe |
| Gas flow | Ar: 30 SCCM | O₂: 4 SCCM |

| | |
|---|---|
| Chamber gas | 2.2 mTorr |
| pressure | |

| | | |
|---|---|---|
| Voltage | ≈300 V | — |
| Current | 0.5 A | — |

| | |
|---|---|
| Deposition | 30 min |
| time | |
| θ | 60° to 85° |
| Deposition | 25 nm/min |
| speed | |

For preparation of a liquid crystal optical device, a substrate provided with an electrode is used. In a transmission type liquid crystal display, an alignment film is formed on a transparent glass substrate provided with an electrode of ITO (indium tin oxide). In the case of a reflection type liquid crystal display, one of a pair of substrates is a transparent glass substrate provided with the ITO electrode and the other substrate is, e.g., a silicon substrate provided with a reflection electrode of aluminum or the like. On these substrates, an alignment film is formed by the film forming method of the present invention and the two substrates are applied to each other to prepare a liquid crystal cell.

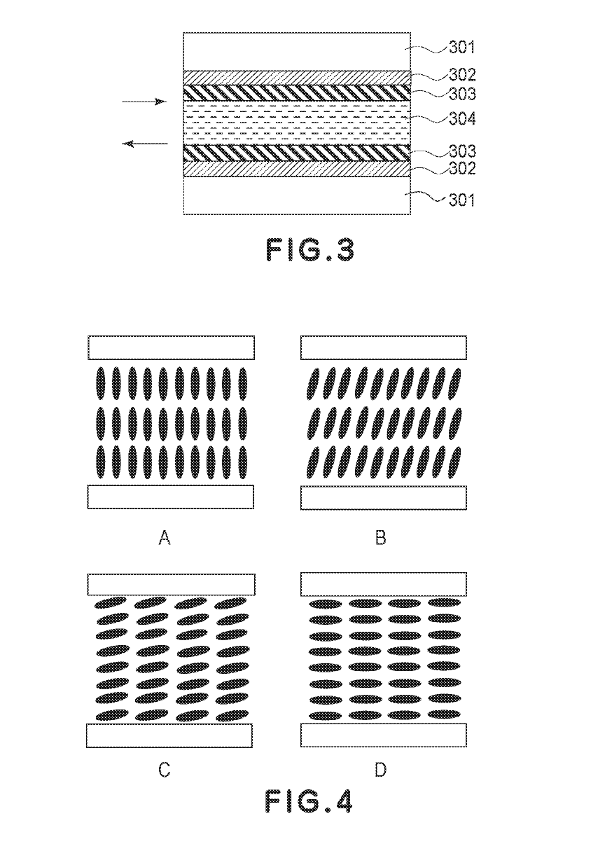

FIG. 3 is a schematic sectional view of the liquid crystal cell (liquid crystal device) prepared in this example. Referring to FIG. 3, the liquid crystal cell includes a pair of glass substrates 301, ITO electrode films 302, alignment films 303, and a liquid crystal layer 304. The alignment films 303 are formed of a material comprising SiO₂ by the film forming method of the present invention. Reference numerals represent incident directions of sputtering particles with respect to the two alignment films, respectively.

The liquid crystal cell shown in FIG. 3 is prepared by applying the upper and lower substrates to each other so that the incident directions of the sputtering particles are parallel and opposite to each other (i.e., anti-parallel). A spacing between the substrates is kept at a constant value by an unshown spacer. As a liquid crystal for filling the spacing, a material having a negative dielectric anisotropy is selected.

In the case of alignment in an OCB (optically compensated bend) mode, the substrates are applied to each other with parallel ion irradiation directions.

FIG. 4 includes substrates for illustrating alignment states of liquid crystal molecules in liquid crystal cells.

FIG. 4 shows, at A, a complete homeotropic alignment mode in which a long axis of the liquid crystal molecules 401 is oriented perpendicularly to the substrates.

FIG. 4 shows, at B, a homeotropic alignment mode with a pretilt angle in which a long axis of liquid crystal molecules 401 is inclined from a direction of a normal to the substrate with a certain angle.

FIG. 4 shows, at C, a homogeneous alignment mode with a pretilt angle in which a long axis of liquid crystal molecules 401 rises from a substrate surface with a certain angle.

FIG. 4 shows, at D, a complete homogeneous alignment mode in which liquid crystal molecules 401 are completely horizontally aligned between the alignment films with respect to the substrate surfaces.

The liquid crystal alignment film obtained in this example by the film forming method of the present invention shows the alignment state at B of FIG. 4. From darkness of liquid crystal alignment in a cross-nicol condition, an inclination (tilt) angle of the liquid crystal molecules from a normal to the substrate is estimated as about 3 deg. When a voltage is applied, the liquid crystal molecules are gradually inclined. In correspondence therewith, a transmittance is gradually increased. An inclination azimuth can be known from an extinction position in the cross-nicol condition.

A pretilt angle is measurable by preparing a cell for measuring the inclination angle separately from the liquid crystal device and performing a known crystal rotation method.

Not apply only to this example, when the alignment film formed by the film forming method of the present invention is used, a rotation angle and a pretilt angle obtained from the rotation angle are positive values. From these results, it is found that the inclination azimuth of the liquid crystal is deviated 180 deg. from an irradiation azimuth of the sputtering particles, i.e., an ion beam irradiation angle and the liquid crystal inclination angle are located opposite from each other with respect to the normal to the substrate. This coincides with results in many oblique deposition methods.

The alignment film prepared in this example by the film forming method of the present invention has a column structure with a column width (thickness) of 10 nm or more at least insofar as the alignment film is observed through an electron microscope. The column width is larger than that in the conventional oblique deposition. This may be attributable to such a phenomenon that energy of the sputtering particles is about 10 times larger than energy of oblique deposition particles and kinetic energy is not lost even on the substrate to increase a diffusion length (distance), with the result that a nucleation density for column formation is suppressed at a low level to allow formation of the column structure with the large column width. The alignment film formation by the film forming method of the present invention using the sputtering is characterized in that inclination alignment close to the vertical alignment as in the oblique deposition can be obtained although the alignment film is a film with a large column width. The liquid crystal device is prepared by using the film obtained by the film forming method of the present invention, so that it is possible to prepare an alignment film with high durability of performance which cannot be realized by the oblique deposition.

### (Application to Liquid Crystal Projector)

As described above, according to the sputtering film forming method of the present invention, it is possible to prepare the alignment film with high durability. On two substrates, an Si oxide film is formed in the same condition and at the same sputtering position by the film forming method of the present invention. The thus prepared substrates are used as a pair and are disposed opposite to each other so that sputtering directions for the two substrates are anti-parallel to each other and thereafter are applied to each other with a sealing agent containing silica beads having a diameter of 3.0 μm to form a cell. After the application, the sealing agent is cured by irradiation with ultraviolet rays while applying a load. The cell after the curing exhibits uniform interference color and a cell thickness is controlled with an error of 3% or less with respect to a designed value (3.0 μm). Incidentally, a pattern of the sealing agent includes an injection part for injecting a liquid crystal through the port.

Into the thus prepared liquid crystal cell, the liquid crystal is injected from the injection port. The liquid crystal used is a liquid crystal material (“MLC-6608”, mfd. by Merck Ltd. Japan). It is clarified that this liquid crystal shows substantially vertical alignment on a conventional silica oblique deposition film by study of the present inventors. The injection of the liquid crystal is performed by holding the liquid crystal cell in a vacuum chamber and applying the liquid crystal to the liquid crystal injection port after evacuation, followed by gradual restoration of the pressure to ambient pressure. The cell after the injection is sealed at the injection port to be subjected to measurement.

As a result of observation of the cell, after the liquid crystal injection, disposed between polarizers arranged in a cross-nicol relationship, it is found that the liquid crystal molecules assume a substantially vertical alignment state in the cell. Though eye observation, an alignment defect portion is not observed. Further, through microscopic observation, a uniform alignment state is achieved even in a minute area.

A dependency of a transmittance on an applied voltage is examined by connecting lead lines to the upper and lower electrodes of the cell and disposing the cell between the two polarizers arrange in the cross-nicol relationship. The liquid crystal cell is disposed so that a direction of inclination of the liquid crystal molecules from a vertical direction coincides with a polarization direction of the polarizer disposed above the liquid crystal layer.

The liquid crystal device prepared by using the alignment film formed by the film forming method of the present invention is kept at 70° C. and continuously irradiated with white light at 10 W/cm², thus being subjected to a durability test as to whether or not a display non-uniformity occurs. As a result, the display non-uniformity does not occur even after 1000 hours or more of the durability test, so that it is confirmed that a liquid crystal display apparatus including the alignment film formed by the film forming method of the present invention shows excellent display stability.

### Example 2

An liquid crystal alignment film of this example can be formed by a sputtering film forming apparatus shown in FIG. 6, which is a schematic view for illustrating the sputtering film forming apparatus used in a liquid crystal alignment film forming process in the present invention. In this example, instead of the oxygen gas supply means used in Example 1, a sputtering apparatus with an SiO₂ cathode as an oxygen radical supply source is provided. Further, in this example, a metal-mode mesh 111 for covering a surface of an SiO₂ target 110 is disposed. From an oxygen gas supply pipe 109, oxygen gas is introduced. From an unshown electric power supply means, electric power is supplied to the SiO₂ target to permit selective sputtering of the SiO₂ target and by appropriately adjusting an oxygen gas flow and a cathode voltage applied, oxygen radical can be supplied to the substrate 106. A metal mesh 108 is disposed so as to cover a surface of a Si target 101. A material for the metal mesh may preferably be a non-magnetic material from the viewpoint of prevention of the influence of a magnetic field in a magnetron sputtering method. The mesh is formed of a metallic material so as to spatially confine plasma generated around the Si target. Particularly, such a constitution is effective in suppression of abnormal discharge such as spark or the like in the case of supplying high electric power to the Si cathode. As another function of the mesh, it is also possible to prevent diffusion of the oxygen gas, supplied to the neighborhood of the substrate, toward the neighborhood of the Si target surface.

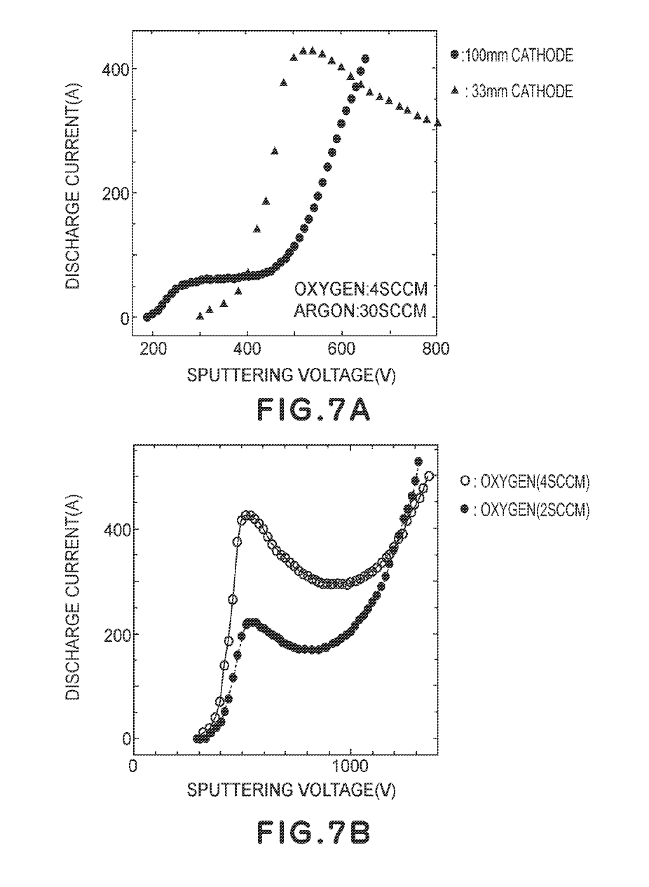

FIG. 7A shows a state of an electric discharge characteristic of the sputtering source in the case of forming the SiO₂ film. In this case, an oxygen gas flow rate is 4 SCCM and Ar gas flow rate is 30 SCCM. In order to prevent arc discharge, an unshown DC power source for applying a pulse (10 kHz; 10 psec) is employed. As an SiO₂ target sputtering source, a pulse power source (not shown) for applying a pulse (40 kHz; duty ratio=50%) is employed.

In this way, it is understood that a 33 mm sputtering source for supplying Si sputtering particles is operated in a metal mode and a 100 mm sputtering source for supplying oxygen radicals is operated in an oxide mode during the sputtering.

FIG. 7B shows an electric discharge characteristic of 100 mm target in the case of changing an amount of oxygen gas introduction. When the oxygen gas flow rate is creased, a gas pressure in the sputtering source is increased, so that a discharge current is increased. Further, a formation speed of the oxide film of SiOₓ is increased, so that a sputtering voltage changed to the metal mode is shifted to a high-voltage side. In FIG. 7B, it is shown that the apparatus in this example is in the oxide mode at the sputtering voltage of 500 V or less, in a transition region in a sputtering voltage range from about 500 V to 900 V, and in the metal mode at the sputtering voltage of 1000 V or more during the sputtering.

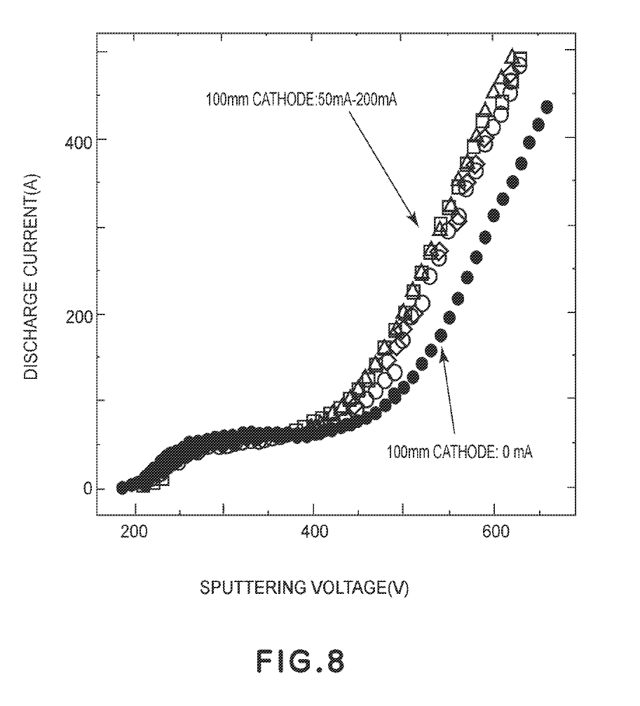

FIG. 8 shows a result of study on the influence of the electric discharge of the 100 mm target on the electric discharge characteristic of the 33 mm target. From the result, it is understood that a discharge current of the 33 mm target in the metal mode is increased by electrically discharging the 100 mm target. However, the discharge current of the 33 mm target little depends on that of the 100 mm target. This may be attributable to separation of the respective sputtering sources by the meshes.

A sputtering condition and an oxidation condition in this example are shown in Table 2 below.

A discharge current for a 33 mm target is constant at 350 mA. This current density includes a current density exceeding 100 mA/cm² in an erosion region, thus resulting in sputtering at a very high current density.

TABLE 2
(SiO₂ obliquely incident film preparation condition)

| | Si target | SiO₂ target |
|---|---|---|
| Target | (33 mmφ) | (100 mmφ) |
| Gas flow | Ar: 30 SCCM | O₂: 0, 2, 4 SCCM |

| | |
|---|---|
| Chamber gas | 2.2 mTorr |
| pressure | |

| | | |
|---|---|---|
| Voltage | ≈640 V | 0 to 450 V |
| Current | 0.35 A | 0 to 0.2 A |

| | |
|---|---|
| Deposition | 30 min |
| time | |
| θ | 60° to 80° |
| Deposition | 35 to 26 nm/min |
| speed | |

In example 1, the SiO₂ thin film is prepared by using only the sputtering source with the diameter of 33 mm. On the other hand, in this embodiment, the second sputtering source is used to supply oxygen radicals onto the substrate, so that it is possible to form the oxide film at a higher deposition speed.

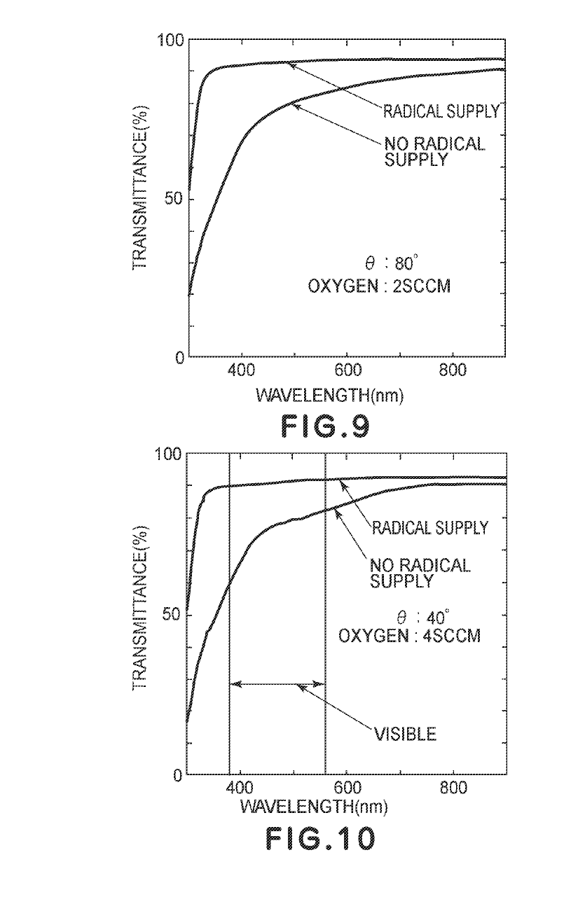

In the case of forming the oxide film at the oxygen gas flow rate of 4 SCCM, as shown in FIG. 2, a transparent SiO₂ thin film which has been completely oxidized is formed at the incident angles θ of 70 deg. or more. In the case where the sputtering is performed by decreasing the oxygen gas flow rate to 2 SCCM, as shown in FIG. 9, a film having a poor transmittance with much absorption is formed when no oxygen radical is supplied. When the oxygen radicals are supplied by actuating the 100 mm target sputtering source, as shown in FIG. 9, oxidation is accelerated to form a transparent film. According to ESCA, the presence of SiO₂ bonds is dominant, so that the formed oxide film is the SiO₂ film. The change in film structure depending on the presence/absence of oxygen radical supply is not clarified but there is no remarkable difference between these two films from AFM images. The thickness of the film formed on the substrate is somewhat decreased by the supply of oxygen radicals. The reason of this is not clarified as yet but the present inventors infer that a state of the target surface during the sputtering is changed to decrease an amount of ejected sputtering particles since the discharge characteristic is affected by actuating the 100 mm target sputtering source.

In the case where the oxygen gas flow rate is 4 SCCM, a larger amount of Si atoms is supplied to the substrate at a smaller incident angle θ, so that oxygen is insufficient, thus resulting in a film with much absorption.

FIG. 10 shows a transmittance of a film formed at an incident angle θ of 40 deg. Also in this case, when oxygen radicals are supplied by actuating the 100 mm target sputtering source, oxidation is accelerated, so that a transparent film is formed. With respect to a distribution of the film thickness on the substrate, similarly as in the case of the incident angle θ of 80 deg., the film deposition speed is decreased when the film is formed while supplying the oxygen radicals. As described above, by supplying the oxygen radicals onto the substrate, it is clear that the oxidation on the substrate is accelerated. This result suggests that it is possible to form the film at a higher deposition speed by supplying a larger amount of Si atoms, thus showing effectiveness of utilization of the sputtering film forming method of the present invention.

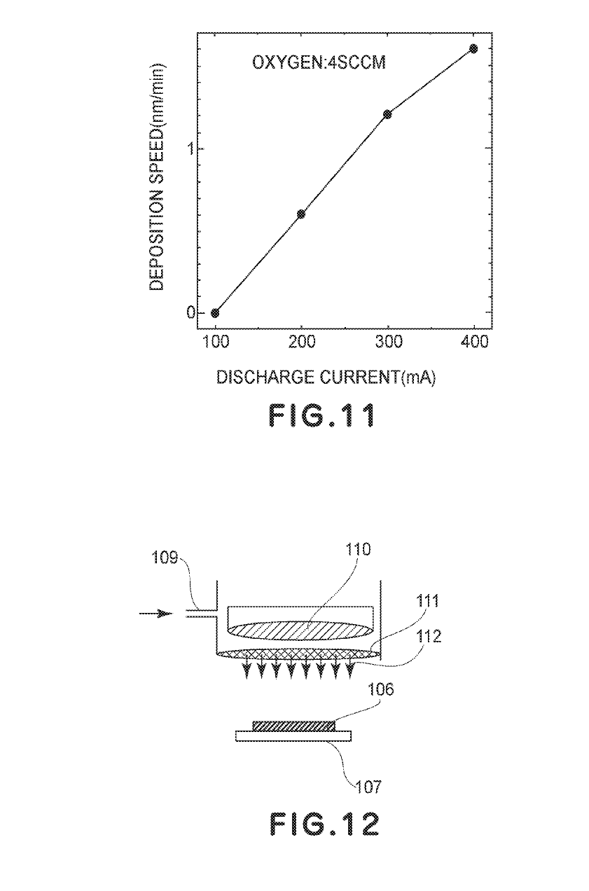

On the other hand, in the case where the 100 mm target sputtering source is used as an oxygen radical supply source, it is considered that Si atoms are somewhat ejected by the sputtering to reach the substrate. In this case, the Si atoms ejected from the sputtering source are incident onto the substrate at a small incident angle, so that there is a possibility that the Si atoms adversely affect obliquely incident deposition. In the case of sputtering in the oxide mode, an amount of Si atoms deposited on the substrate is examined by measuring the deposition speed of the film. In this case, the substrate is disposed opposite to the sputtering source as shown in FIG. 12. When the sputtering is performed by changing the discharge current in the oxide mode region, measured deposition speeds are shown in FIG. 11, it is understood that only a film of 10 nm or less is formed even in the sputtering for 2 hours at the discharge current of 200 mA, thus resulting in little sputtering of the Si atoms. Even when the discharge current is increased to 400 mA, the deposition speed is as small as merely 1.7 nm/min. This means that the sputtering source principally functions as the oxygen radical supply source in the case of the sputtering in the oxide mode.

The alignment film prepared in this example by the film forming method of the present invention has a column structure with a column width (thickness) of 10 nm or more at least insofar as the alignment film is observed through an electron microscope. The column width is larger than that in the conventional oblique deposition. This may be attributable to such a phenomenon that energy of the sputtering particles is about 10 times larger than energy of oblique deposition particles and kinetic energy is not lost even on the substrate to increase a diffusion length (distance), with the result that a nucleation density for column formation is suppressed at a low level to increase the column width. As described in Example 1, the alignment film formation by the film forming method of the present invention using the sputtering is characterized in that inclination alignment close to the vertical alignment as in the oblique deposition can be obtained although the alignment film is a film with a large column width. The liquid crystal device is prepared by using the film obtained by the film forming method of the present invention, so that it is possible to prepare an alignment film with high durability of performance which cannot be realized by the oblique deposition.

### (Application to Liquid Crystal Projector)

As described above, according to the sputtering film forming method of the present invention in this example, similarly as in Example 1, it is possible to prepare the alignment film with high durability. On two substrates, an oxide film is formed in the same condition and at the same sputtering position as in Example 1 by the film forming method of the present invention. The thus prepared substrates are used as a pair and are disposed opposite to each other so that sputtering directions for the two substrates are anti-parallel to each other and thereafter are applied to each other with a sealing agent containing silica beads having a diameter of 3.0 μm to form a liquid crystal cell in the same manner as in Example 1.

Into the thus prepared liquid crystal cell, the liquid crystal is injected from the injection port in the same manner as in Example 1. The liquid crystal used is a liquid crystal material (“MLC-6608”, mfd. by Merck Ltd. Japan). It is clarified that this liquid crystal shows substantially vertical alignment on a conventional silica oblique deposition film by study of the present inventors. The injection of the liquid crystal is performed by holding the liquid crystal cell in a vacuum chamber and applying the liquid crystal to the liquid crystal injection port after evacuation, followed by gradual restoration of the pressure to ambient pressure. As a result, the liquid crystal is successfully injected into the cell. The cell after the injection is sealed at the injection port to be subjected to measurement.

As a result of observation of the cell, after the liquid crystal injection, disposed between polarizers arranged in a cross-nicol relationship, it is found that the liquid crystal molecules assume a substantially vertical alignment state in the cell. Though eye observation, an alignment defect portion is not observed. Further, through microscopic observation, a uniform alignment state is achieved even in a minute area.

A dependency of a transmittance on an applied voltage is examined by connecting lead lines to the upper and lower electrodes of the cell and disposing the cell between the two polarizers arrange in the cross-nicol relationship. The liquid crystal cell is disposed so that a direction of inclination of the liquid crystal molecules from a vertical direction coincides with a polarization direction of the polarizer disposed above the liquid crystal layer.

The liquid crystal device prepared by using the alignment film formed by the film forming method of the present invention is kept at 70° C. and continuously irradiated with white light at 10 W/cm², thus being subjected to a durability test as to whether or not a display non-uniformity occurs. As a result, the display non-uniformity does not occur even after 1000 hours or more of the durability test, so that it is confirmed that a liquid crystal display apparatus including the alignment film formed by the film forming method of the present invention shows excellent display stability.

### INDUSTRIAL APPLICABILITY

According to the present invention, there is provided a forming method of an Si oxide film in which the Si oxide film excellent in durability can be obtained at a high deposition speed.

The present invention is also capable of providing an alignment film of an inorganic material excellent in durability at a high deposition speed.

The present invention is further capable of providing a liquid crystal optical device using the above described alignment film.

The Si oxide film forming method of the present invention can form the Si oxide film excellent in durability at a high deposition speed, so that the forming method can be utilized in a production process of a liquid crystal alignment film or a liquid crystal optical device.

While the invention has been described with reference to the structures disclosed herein, it is not confined to the details set forth and this application is intended to cover such modifications or changes as may come within the purpose of the improvements or the scope of the following claims.

1. A method of forming a silicon oxide film on a substrate comprising steps of:
sputtering a silicon target to generate silicon particles; and
bombarding the substrate with the silicon particles from an oblique direction while supplying oxygen gas onto the substrate.

2. A method according to claim 1, wherein an incident angle of the silicon particles on the substrate is set in a range from 60 deg. to 90 deg.

3. A method according to claim 1, wherein the substrate is disposed so that a surface thereof is inclined from a direction in which the silicon particles are generated toward a supply source of the oxygen gas.

4. A method according to claim 1, wherein a surface of the silicon target is covered with a mesh of an electroconductive member.

5. A method according to claim 1, wherein an amount of supply of the oxygen gas is smaller than an amount at which a surface of the silicon target is oxidized.
